(19) United States
(12) Patent Application Publication
(10) Pub. No.: US 2011/0259526 A1
(43) Pub. Date: Oct. 27, 2011

(54) SONOTRODE MOUNTING SYSTEM

(75) Inventor: Frank Eder, Spaichingen (DE)

(73) Assignee: Maschinenfabrik Spaichingen GmbH, Spaichingen (DE)

(21) Appl. No.: 13/095,079

(22) Filed: Apr. 27, 2011

(30) Foreign Application Priority Data
Apr. 27, 2010 (DE) 102010018444.6

(51) Int. Cl. B32B 37/02; B32B 38/04; B32B 38/00; H05K 7/14

(52) U.S. Cl. 156/510; 248/226.11; 156/349

(57) ABSTRACT

A sonotrode mount system is provided having at least one generally U-shaped clamp supportable at a carrier and including a web and two arms respectively elastically tiltable about a node point provided in a web region and between which an ultrasonic sonotrode is clampable. At least the free ends of the arms contact the sonotrode on a clamped sonotrode. The clamp is supportable at the carrier in the web region, wherein it is preferably supportable at the carrier in the node point of the tilt movements. Such a sonotrode mount system can be provided, in particular for the holding of a vibrating structure of an ultrasonic system which is part of an apparatus for sealing, connecting, separating, perforating and/or shaping of materials, such as in particular plastics, foils, non-woven fabrics, fabrics/textiles and/or paper.

The invention relates to a system for holding a vibrating structure of an ultrasonic system including a sonotrode and in particular to a sonotrode mount system. The invention further relates to an apparatus for sealing, connecting, separating, perforating and/or shaping of materials, such as, in particular, plastics, foils, non-woven fabrics, fabrics/textiles and/or paper, including an ultrasonic system having such a sonotrode mount system.

Ultrasonic systems having vibrating structures with at least one sonotrode and a converter, having an ultrasonic generator exiting the converter, as well as an anvil disposed opposite of the sonotrode are already known as such. In this respect the ultrasonic generator generates an alternating current which is converted by the converter into a mechanical oscillation generally in accordance with the piezoelectric transducer principle. This mechanical oscillation is transferred to the materials to be processed via the coupled vibrating structure. Should, for example, a connection be produced then the material to be connected is plastified at the contact surface through the cooperation of the physical boundary conditions between the anvil and the sonotrode, this means that it is plastified, in particular by means of sonic reflection, of sonic absorption and of boundary surface friction, whereby the concerned materials, in particular plastics, foils, non-woven fabrics, fabrics/textiles and/or paper are welded to one another. A prerequisite for the welding is a small minimum proportion of a thermoplastic plastic.

The vibrating structure of the ultrasonic system can in principle also include an amplitude transformation piece switched between the converter and the sonotrode. The contact surface of the sonotrode coming into contact with the materials to be processed can, in particular be planar. In this case, for example, the welding contours etc. are provided at the anvil. Sonotrode and anvil can be moved towards one another and away from one another. Also a plurality of sonotrodes and/or vibrating structures can be arranged next to one another.

In a system for holding the vibrating structure of an ultrasonic system known from DE 20 2004 003 917 U1 at least four auxiliary boosters are arranged at the sonotrode, an end of each is fixedly connected with the sonotrode and the other end is respectively capable of vibration and the sonotrode is supportedly inserted into an opening of a holder. In this respect the auxiliary boosters can be supported at the carrier in these arising vibration nodes of the longitudinal vibrations arising in the vibrating structure.

The invention is based on the object of providing a sonotrode system which, for an as simple as possible robust setup enables a reliable, stable holding of the vibrating structure of an ultrasonic system. Furthermore, the exchange of a respective vibrating structure or of parts of this vibrating structure from a composition should be simplified. Moreover, a correspondingly improved apparatus of the initially mentioned kind should be provided.

In accordance with this invention this object is satisfied by a sonotrode mount system having at least a generally U-shaped clamp supportable at a carrier and including a web and two arms which are respectively elastically tiltable about a node point provided in a web region and with an ultrasonic sonotrode being clampable between the arms, wherein, on a clamped sonotrode, at least the free ends of the arms contact the sonotrode and the clamp is supportable at a carrier in the web region.

Due to this formation, a very stable setup of the mount system arises overall, whereby the operating safety is correspondingly increased. The parts supporting the sonotrode and/ or the vibrating structure can be made relatively solid, whereby a robust support is achieved. At most small changes in shape of the clamp arise when subjected to mechanical load. Furthermore, a simple exchange of a respective vibrating structure or parts of this vibrating structure from a composite is now also possible due to the design in accordance with the invention.

Preferably, the free ends of the arms of a respective generally U-shaped clamp are each provided with a notch into which a projection provided at the sonotrode engages on a clamped sonotrode. In this respect the projection can be relatively small and can, for example, be formed by an especially small chamfered surface.

Alternatively, however, also the free ends of the arms of a respectively generally U-shaped clamp can each be provided with a corresponding projection which engages into a corresponding notch of the sonotrode on a clamped sonotrode. In this example the projection is also preferably relatively small again.

The cooperating projections and notches are each preferably dimensioned such that the tilt movements of the arms around the node point taking place on a clamped sonotrode, in particular due to transverse oscillations of the sonotrode, are not impaired.

The clamp is preferably supportable at the carrier in the node point of the tilt movements.

In accordance with an expedient practical design of the sonotrode mount system in accordance with the invention recesses supporting the tilt movements of the arms are provided in the web region of a respective generally U-shaped clamp.

It is in particular also of advantage when the web of a respective generally U-shaped clamp is divided into two web sections associated with a respective arm and in which the web sections for the formation of the U-shaped clamp are releasably connected to one another, e.g. liftable.

A respective recess can be provided in each web section which respectively supports a tilt movement of the associated arm.

In accordance with a preferred practical embodiment of the sonotrode mount system in accordance with the invention, it is provided that the free ends of the arms of a respective generally U-shaped clamp contact and/or enter into engagement with the sonotrode in the vibration node of the longitudinal vibration generated in the sonotrode.

The sonotrode mount system in accordance with the invention ensures a stable holding of the vibrating structure of an ultrasonic system. In this respect the mount preferably engages in the vibration node of the longitudinal vibration generated in the sonotrode where it can be spanned. The perpendicular elongating movements of the sonotrode arising there cause a co-moving of the generally U-shaped clamp in the form of a transverse vibration. Through a corresponding design of the mount a tilt movement arises at its foot, this means in the web region of the generally U-shaped clamp. The clamp is preferably supported or fixed, for example at a carrier plate in the node point of this tilt movement at the carrier. The mount is thus preferably stored in the node point of a tilt movement.

In accordance with the invention the aforementioned object is further satisfied by an apparatus for sealing, connecting, separating, perforating and/or shaping of materials, such as in particular plastics, foils, non-woven fabrics, fabrics/textiles and/or paper having an ultrasonic system which includes a vibrating structure having at least a sonotrode and a converter, an ultrasonic generator exciting the converter, an anvil diposed opposite the sonotrode, as well as a sonotrode mount system in accordance with the invention associated with the sonotrode, wherein the free ends of the arms of the respective generally U-shaped clamp preferably contacts and/or enters into engagement with the sonotrode in the vibration node of the longitudinal vibration generated in the sonotrode.

The invention will be described in the following with reference to embodiments by means of the drawing; in this is shown:

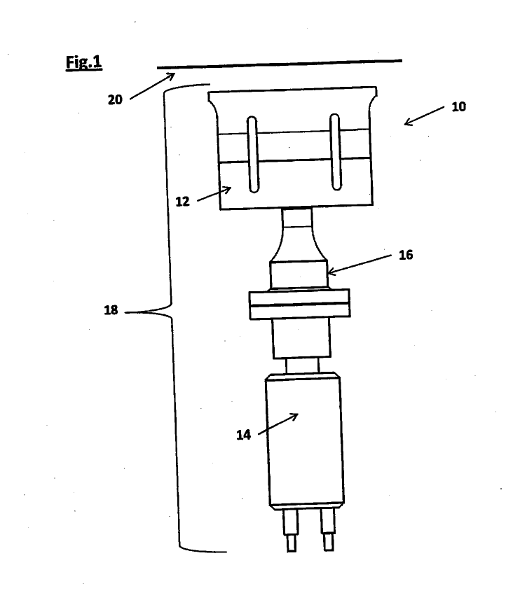

FIG. 1 a schematic illustration of an exemplary embodiment of an ultrasonic system;

FIG. 2 a schematic perspective illustration with a exemplary embodiment of a sonotrode mount system in accordance with the invention; and

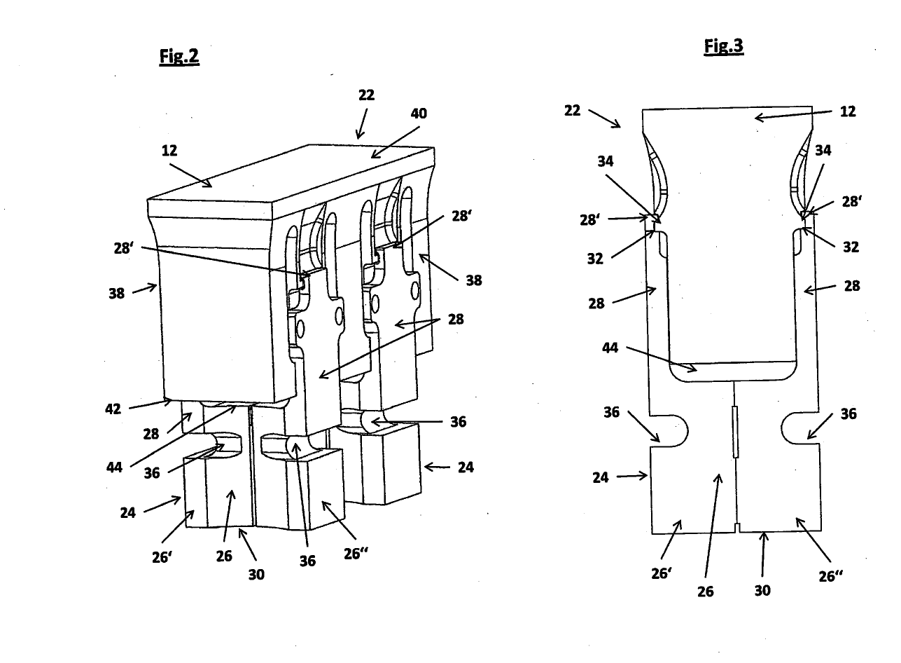

FIG. 3 a schematic sectional drawing of the sonotrode mount system in accordance with FIG. 2.

FIG. 1 shows in a schematic illustration of an exemplary embodiment of an ultrasonic system 10, an apparatus for sealing, connecting, separating, perforating and/or shaping of materials, such as, in particular plastics, foils, non-woven fabrics, fabrics/textiles and/or paper which amongst other things are also suitable for the manufacture of packagings.

The ultrasonic system 10 includes at least a sonotrode 12 a vibrating structure 18 which has a converter 14 and possibly has an amplitude transformation piece 16, an ultrasonic generator (not shown) exiting the converter 14, as well as an anvil 20 disposed opposite of the sonotrode 12. The sonotrode 12 and the anvil 20 can be moved towards one another and away from one another.

FIG. 2 shows in a schematic perspective illustration an exemplary embodiment of a sonotrode mount system 22 in accordance with the invention which can, for example, be associated with the sonotrode 12 of such an ultrasonic system 10, as is illustrated in FIG. 1.

The sonotrode mount system 22 includes at least one generally U-shaped clamp 24 having a web 26 and two arms 28 supportable at a carrier (not shown) with the arms being respectively elastically tiltable about a node point 30 provided in a region of the web 26 and with an ultrasonic sonotrode 12 being clampable between the arms, wherein, on a clamped sonotrode 12, at least the free ends 28′ of the arms 28 contact and/or enter into engagement with the sonotrode 12 and the clamp 24 is supportable at the carrier in the web region.

As can be recognized with reference to FIG. 2, two generally U-shaped clamps 24 are provided in the present example.

The sonotrode 12 can have a generally cuboid, elongated shape and the two arms 28 of a respective clamp 24 can generally extend perpendicular to the sonotrode longitudinal axis on the two longitudinal sides of the sonotrode 12 disposed opposite from another when a sonotrode 12 is clamped between these. In this respect the web 26 of the generally U-shaped clamp 24 is arranged on the sonotrode side 42 disposed remote from the contact side 40 of the sonotrode 12 coming into contact with the materials to be processed on a clamped sonotrode 12. A free intermediate space 44 is provided between the sonotrode side 42 disposed remote from the contact side 40 and the web 26 of the clamp 24.

As can be recognized, in particular also with reference to FIG. 3, in which the sonotrode mount system 22 in accordance with FIG. 2 is illustrated in a schematic section drawing, the free ends 28′ of the arms 28 of the respective generally U-shaped clamp 24 are, for example, each provided with a notch 32 into which a projection 34 provided at the sonotrode 12 enters into engagement on a clamped sonotrode 12 in the present example.

However, in principle also such embodiments are plausible in which, for example, the free ends 28′ of the arms 28 of a respective generally U-shaped clamp 24 are each provided with a projection which enters into engagement with a notch of the sonotrode 12 on a clamped sonotrode 12.

The respectively cooperating projections 34 and notches 32 are dimensioned such that on tilt movements of the arms 28 about the node point 30 arising on a clamped sonotrode 12 are not impaired.

A respective generally U-shaped clamp 24 is preferably stored and/or supported at the carrier in the node point 30 of the tilt movements.

Recesses 36 supporting the tilt movements of the arms 28 are provided in the web region of a respective generally U-shaped clamp 24. As can be recognized in FIGS. 2 and 3 these recesses 36 can be introduced, in particular on sides of the web 26 lying opposite from one another and can each extend parallel to the sonotrode longitudinal direction.

The web 26 of the respective generally U-shaped clamp 24 can be divided into two web sections 26′, 26″ each associated with one of the arms which are connected to one another, in particular are releasably connected to one another, for the formation of the U-shaped clamp 24 and/or its webs 26. In this respect the web sections 26′, 26″ can, for example be screwed together. As can be recognized with reference to FIGS. 2 and 3 recesses 36 are provided in each web section 26′, 26″ each supporting the tilt movements of the associated arm 28.

The free ends 28′ of the arms 28 of a respective generally U-shaped clamp 24 preferably engage in the vibration node of the longitudinal vibration of the sonotrode 12 generated in the sonotrode 12. Thus, in the present case the projections 34 and notches 32 enter into engagement with one another in the vibrating node of the longitudinal vibration generated in the sonotrode 12.

As can be recognized with reference to FIGS. 2 and 3, the web sections 26′, 26″ forming the web 26 of the respective generally U-shaped clamp 24 can each be designed as a respective pedestal-like foot connected at the related end of the associated arm 28. The node point 30 of the tilt movements preferably lies at the side of the web 26 and/or at the web sections 26′, 26″ remote from the arms 28. A respectively generally U-shaped clamp 24 can then, for example, be supported on a carrier, e.g. a carrier plate, by the web surface remote from the arms 28.

Thereby a very stable mount for the vibrating structure of the ultrasonic system is achieved. The mount engages the sonotrode in the vibrating node of the longitudinal vibration generated in the sonotrode and is clamped there. The transverse elongation movement arising there, this means in the region of the free arm ends, causes a co-movement of the respective generally U-shaped clamp in the form of a transverse vibration. Through a corresponding shaping and/or design of the clamp a tilt movement arises at its foot or its web. The respective generally U-shaped clamp can be fixed in the node point of this tilt movement which, can lie, in particular on the end surfaces of the webs remote from the arms, for example, at a carrier, e.g. a carrier plate.

On mechanical loading at most small form changes of the generally U-shaped clamp arise. Furthermore, a simple exchange of a respective vibrating structure or parts of this vibrating structure from a compound are possible.

Thereby a generally very stable mount of the vibrating structure results, whereby a high operational safety is achieved.

The parts supporting the vibrating structure can be carried out more solidly by means of the sonotrode mount system in accordance with the invention, whereby the mount becomes more robust. Preferably a respective generally U-shaped clamped is stored in the node point of the tilt movements.

### List of Reference Numerals

10 ultrasonic system
12 sonotrode
14 converter
16 amplitude transformation piece
18 vibrating structure
20 anvil
22 sonotrode mount system
24 generally U-shaped clamp
26 web
26′ web section
26″ web section
28 arm
28′ free arm end
30 node point
32 notch
34 projection
36 recess
38 longitudinal sides
40 contact side
42 the side remote from the contact side
44 intermediate space

1. A sonotrode mount system (22) having at least one generally U-shaped clamp (24) supportable at a carrier and including a web (26) and two arms (28) each with a free end (28′), with the arms being respectively elastically tiltable about a node point (30) provided in a web region and with an ultrasonic sonotrode (12) being clampable between the arms, wherein, on a clamped sonotrode (12), at least the free ends (28′) of the arms (28) contact the sonotrode and the clamp (24) is supportable at the carrier in the web region.

2. A sonotrode mount system in accordance with claim 1, wherein the free ends (28′) of the arms (28) of a respective generally U-shaped clamp (24) are each provided with a notch (32) into which a projection (34) provided at the sonotrode (12) engages on a clamped sonotrode (12).

3. A sonotrode mount system in accordance with claim 1, wherein the free ends (28′) of the arms (28) of a respective generally U-shaped clamp (24) are each provided with a projection which engage into a notch of the sonotrode (12) on a clamped sonotrode (12).

4. A sonotrode mount system in accordance with claim 1, wherein each of the cooperating projections (34) and notches (32) are dimensioned such that the tilt movements of the arms (28) around the node point (30) taking place on a clamped sonotrode (12) are not impaired.

5. A sonotrode mount system in accordance with claim 1, wherein a respective generally U-shaped clamp (24) is supportable at the carrier in the node point (30) of the tilt movements.

6. A sonotrode mount system in accordance with claim 1, wherein recesses (36) supporting the tilt movements of the arms (28) are provided in the web region of a respective generally U-shaped clamp (24).

7. A sonotrode mount system in accordance with claim 1, wherein the web (26) of a respective generally U-shaped clamp (24) is divided into two web sections (26′, 26″) which are each associated with one of the two arms (28) and with the web sections (26′, 26″) being connectable to one another for the formation of the U-shaped clamp (24).

8. A sonotrode mount system in accordance with claim 7, wherein the web sections for the formation of the U-shaped clamp are releasably connected to one another.

9. A sonotrode mount system in accordance with claim 7, wherein a recess (36) is provided in each web section (26′, 26″) which respectively supports a tilt movement of the associated arm (28).

10. A sonotrode mount system in accordance with claim 1, wherein the free ends (28′) of the arms (28) of a respective generally U-shaped clamp (24) contact and/or enter into engagement with the sonotrode (12) in the vibration node of the longitudinal vibration generated in the sonotrode (12).

11. An apparatus for sealing, connecting, separating, perforating and/or shaping of materials having an ultrasonic system (10) including at least one vibrating structure (18) having a sonotrode (12) and a converter (14), an ultrasonic generator exciting the converter (14), an anvil disposed opposite the sonotrode (12), as well as a sonotrode mount system (22) associated with the sonotrode (12), wherein the sonotrode mount system (22) has at least one generally U-shaped clamp (24) supportable at a carrier and including a web (26) and two arms (28) each with a free end (28′), with the arms being respectively elastically tiltable about a node point (30) provided in a web region and with an ultrasonic sonotrode (12) being clampable between the arms, wherein, on a clamped sonotrode (12), at least the free ends (28′) of the arms (28) contact the sonotrode and the clamp (24) is supportable at the carrier in the web region, wherein the free ends (28′) of the arms (28) of a respective generally U-shaped clamp (24) contact and/or enter into engagement with the sonotrode (12).

12. An apparatus in accordance with claim 11, wherein the free ends (28′) of the arms (28) of a respective generally U-shaped clamp (24) contact and/or enter into engagement with the sonotrode (12) in the vibration node of the longitudinal vibration generated in the sonotrode (12).

13. An apparatus in accordance with claim 11, wherein the materials are plastics, foils, nonwoven fabrics, fabrics/textiles and/or paper.
